(19) United States
(12) Patent Application Publication
(10) Pub. No.: US 2001/0014374 A1
(43) Pub. Date: Aug. 16, 2001

(54) Plasma treatment apparatus and electrode used for the same

(76) Inventors: Nobuhisa Kumamoto, Kyoto (JP); Takahiro Arakawa, Kyoto (JP); Hiroshi Oka, Kyoto (JP); Toshiyuki Hosoi, Kyoto (JP)

Correspondence Address: Michael D. Bednarek, SHAW PITTMAN, 1650 Tysons Boulevard, McLean, VA, 22102-4859, US

(21) Appl. No.: 09/778,753

(22) Filed: Feb. 8, 2001

(30) Foreign Application Priority Data
Feb. 10, 2000 (JP) 2000-32934
Feb. 14, 2000 (JP) 2000-35343
Feb. 14, 2000 (JP) 2000-35344

(51) Int. Cl. H01L 21/00

(52) U.S. Cl. 427/569; 156/345; 118/723 E

(57) ABSTRACT

An electrode used for plasma treatment includes a conductive support and an insulator provided on the upper surface of the support. The upper surface of the support is divided into a first portion upon which a semiconductor substrate to be treated is mounted, and a second portion around the first portion. The insulator covers at least a part of the second portion of the upper surface of the support.

### BACKGROUND OF THE INVENTION

1. Field of the Invention

The present invention generally relates to a plasma treatment apparatus. In particular, the invention relates to an electrode used in a plasma treatment apparatus. The invention also relates to plasma treatment.

2. Description of the Related Art

Conventionally, plasma treatment apparatuses have been widely used for forming required layers on semiconductor substrates (e.g. silicon wafers) or for etching the surface of the substrate. Typically, a plasma treatment apparatus includes a gas-containing chamber, upper and lower electrodes arranged in the chamber in facing relation, and so on. Such a plasma treatment apparatus is disclosed in JP-A-60(1985)-178633 for example. In place of the upper electrode, the plasma treatment apparatus may be provided with a microwave discharger, as disclosed in JP-A-60(1985)-247924 for example.

The conventional plasma treatment apparatus has been found disadvantageous in the following respect.

The plasma treatment apparatus of JP-A-60(1985)-178633, as stated above, includes upper and lower electrodes arranged in facing relation. To subject a semiconductor substrate to plasma surface treatment using the conventional apparatus, the substrate is placed on the lower electrode, and heated up to a predetermined temperature. Thereafter, a high-frequency current is applied to the upper and the lower electrodes, to generate a plasma of the gas contained in the chamber. Thus, a desired layer may be formed on the semiconductor substrate.

In the conventional apparatus, the lower electrode is greater in diameter than the semiconductor substrate subject to the surface treatment. Therefore, with the substrate being placed on the electrode, the radially inner portion of the upper surface of the electrode is covered by the substrate, whereas the radially outer portion around the inner portion is left exposed to the gas contained in the chamber. In this state, the resistivity between the above-mentioned inner portion and the upper electrode tends to be greater than the resistivity between the above-mentioned outer portion and the upper electrode. In addition, the capacitance between the inner portion and the upper electrode tends to be smaller than the capacitance between the outer portion and the upper electrode.

Due to such inequality of resistivity and capacitance, the plasma to be generated between the upper and the lower electrodes may fail to have a uniform density between the upper and the lower electrodes. Specifically, the plasma density between the above-mentioned outer portion and the upper electrode tends to be smaller than the plasma density between the inner portion and the upper electrode. Because of this nonuniformity of plasma density, the layer to be formed on the semiconductor substrate may fail to have a uniform thickness.

The same problem may occur to the apparatus disclosed in JP-A-60(1985)-247924, in which the lower electrode is not entirely covered by a semiconductor substrate to be treated.

### SUMMARY OF THE INVENTION

The present invention has been proposed under the circumstances described above, and an object of the invention is to provide means for performing uniform surface treatment with semiconductor substrates.

According to a first aspect of the present invention, an electrode used for plasma treatment is provided, which includes: a conductor provided with an upper surface which includes a first portion upon which a semiconductor substrate to be treated is mounted and a second portion around the first portion; and an insulating member provided on the upper surface of the conductor for covering at least a part of the second portion.

Preferably, the insulating member may extend upward beyond the first portion for the purpose of holding the semiconductor substrate in place. To this end, alternatively, the first portion may be retreated downward from the second portion, or a plurality of upward projections may be arranged around the first portion. These projections may be made of an insulating material.

Preferably, the insulating member may be spaced from the semiconductor substrate placed on the first portion.

The insulating member may be a plate or a metal oxide layer. The insulating member may be detachable from the upper surface of the electrode.

According to a second aspect of the present invention, a plasma treatment apparatus may be provided which includes: a chamber; a lower electrode arranged within the chamber and provided with an upper surface which includes a first portion upon which a semiconductor substrate to be treated is mounted and a second portion around said first portion; an upper member arranged within the chamber in facing relation to the lower electrode; and an insulating member provided on the upper surface of the lower electrode for covering at least a part of said second portion.

The above-mentioned upper member may be an electrode or a microwave discharger.

According to a third aspect of the present invention, there is provided a method of plasma treatment using an apparatus provided with a chamber, a lower electrode and an upper member facing the lower electrode. The method may include the steps of: providing insulating means around a semiconductor substrate placed on the lower electrode; and causing a plasma discharge between the upper member and the lower electrode.

Other features and advantages of the present invention will become apparent from the detailed description given below with reference to the accompanying drawings.

### BRIEF DESCRIPTION OF THE DRAWINGS

FIG. 1 is a sectional view showing the principal components of a plasma treatment apparatus according to a first embodiment of the present invention;

FIG. 2 is a perspective view showing the lower electrode of the apparatus of FIG. 1;

FIG. 3 is an enlarged sectional view showing a portion of the lower electrode;

FIG. 4 is a sectional view showing the principal components of a plasma treatment apparatus according to a second embodiment of the present invention;

FIG. 5 is a sectional view showing the principal components of a plasma treatment apparatus according to a third embodiment of the present invention;

FIG. 6 is a sectional view showing a portion of the lower electrode of the apparatus of FIG. 5;

FIG. 7 is a graph showing the relation between the obtained layer thickness and the distance from the center of the semiconductor substrate;

FIG. 8 is a sectional view showing the principal components of a plasma treatment apparatus according to a fourth embodiment of the present invention;

FIG. 9 is a perspective view showing the lower electrode of the apparatus of FIG. 8; and

FIG. 10 is an enlarged sectional view showing a portion of the lower electrode of FIG. 8.

### DETAILED DESCRIPTION OF THE PREFERRED EMBODIMENTS

The preferred embodiments of the present invention will be described below with reference to the accompanying drawings.

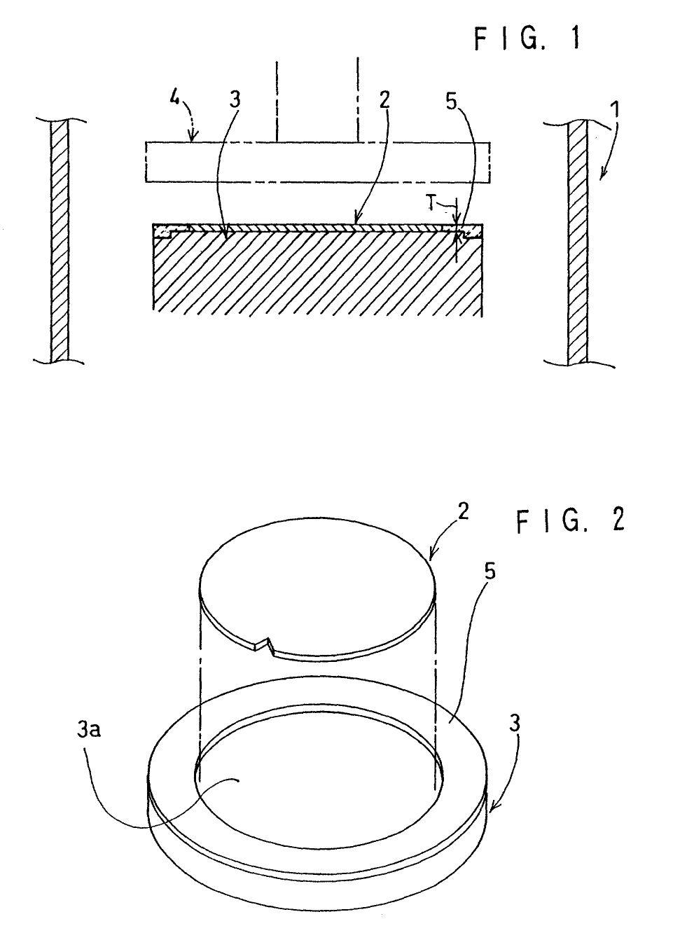

FIG. 1 shows the principal components of a plasma treatment apparatus according to a first embodiment of the present invention. As shown, the apparatus includes a gas-containing chamber 1, a lower electrode 3 made of e.g. aluminum, and an upper electrode 4 arranged in facing relation to the lower electrode 3 within the chamber 1. A semiconductor substrate 2 (such as silicon wafer) to be treated is placed on the lower electrode 3. Though not illustrated, the lower and the upper electrodes 3, 4 are fixed to the chamber 1 via insulating means.

In operation, a high-frequency electrical current is applied to the lower and the upper electrodes 3, 4, thereby generating a plasma therebetween. In this state, a required layer may be formed on the upper surface of the lower electrode 3, or the upper surface may be etched, as required.

As seen from FIGS. 1 and 2, the top surface 3a of the lower electrode 3 is greater in area than the substrate 2. Thus, without taking any countermeasures, the fringe of the top surface 3a is exposed to the contained gas, while the radially inner portion of the top surface 3a is covered by the substrate 2. According to the first embodiment, however, an insulating ring 5, made of e.g. a heat-resistant, insulating material such as alumina, is used to cover the fringe of the top surface 3a. As illustrated, the ring 5 is formed with a hole into which the substrate 2 is fitted. The outer diameter of the ring 5 is equal to the diameter of the top surface 3a of the electrode 3.

With such an arrangement, the top surface 3a as a whole is covered by both the substrate 2 and the ring 5 placed on the lower electrode 3. Thus, the resistivity and capacitance between the two electrodes 3, 4 are generally equalized, whereby the plasma density will be advantageously equalized across the substrate 2 to be treated. Accordingly, the required operation (i.e. forming of the layer or etching of the surface) is performed uniformly.

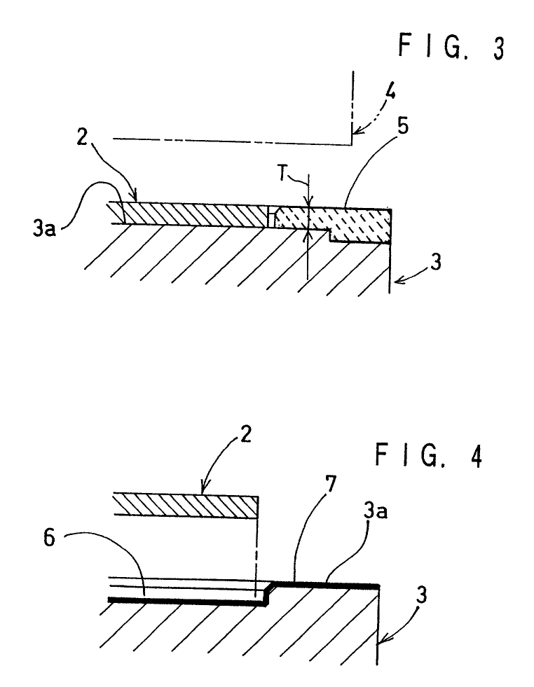

In addition, according to the first embodiment, the upper surface of the ring 5 is higher than the upper surface 3a of the electrode 3 by a predetermined amount T, as shown in FIG. 3. Thus, it is possible to hold the substrate 2 in place on the lower electrode 3 simply by fitting it into the hole of the ring 5.

Reference is now made to FIG. 4 illustrating the principal portions of a plasma treatment apparatus according to a second embodiment of the present invention. The apparatus of the second embodiment is basically similar to the apparatus of the first embodiment except for the following features.

In the second embodiment, the lower electrode 3 is provided, in its upper surface 3a, with a recess 6 into which the substrate 2 to be treated is fitted. In this manner, no positioning ring such as the one used in the first embodiment is required for positioning the substrate 2 on the electrode 3. In the illustrated example, the upper surface 3a of the electrode 3 is entirely covered by an insulating layer 7 which maybe an oxide layer formed by anodic treatment. Accordingly, the equalization of resistivity and capacitance between the two electrodes 3 and 4 is achieved.

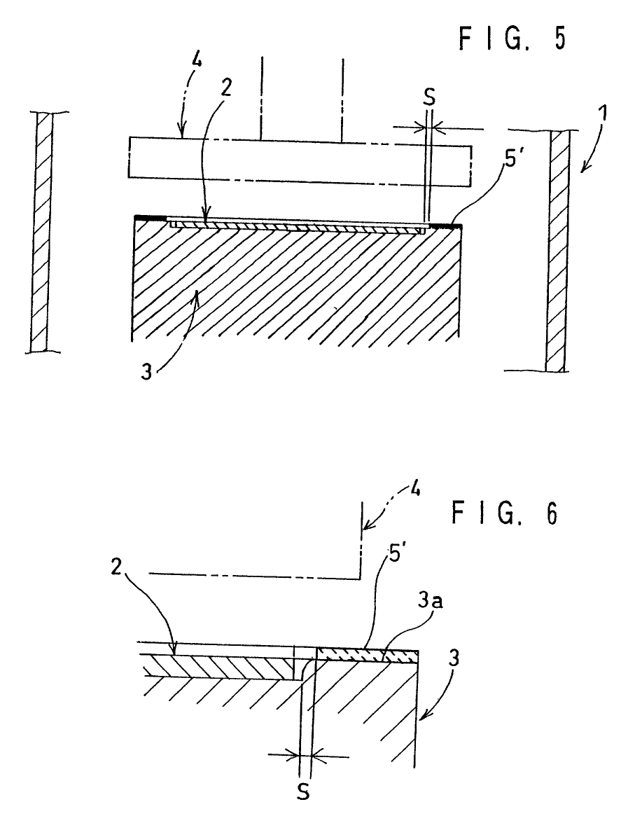

FIGS. 5 and 6 show the principal portions of a plasma treatment apparatus according to a third embodiment of the present invention. In this embodiment again, the substrate 2 to be treated is fitted into a recess 6 formed in the upper surface 3a of the lower electrode 3.

As best shown in FIG. 6, the fringe of the upper surface 3a of the electrode 3 is covered by an insulating ring 5′ which may be made of a heat-resistant material such as alumina. In place of the ring 5′, use may be made of a metal oxide layer formed on the entirety or part of the upper surface 3a of the electrode 3.

In the illustrated example, a clearance S is provided between the inner edge of the ring 5′ and the circumference of the recess 6. According to the experiments conducted by the inventors, the clearance S may preferably be in a range of 8-13 mm (supposing that the diameter of the substrate 2 is 200 mm) to form a layer of a uniform thickness on the substrate 2.

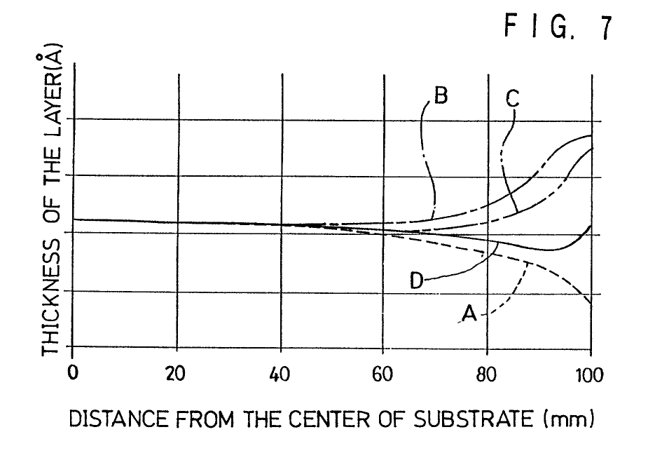

With the clearance S in the above preferable range, the thickness of the resulting layer is substantially equalized, as shown by the curve D (solid line) in the graph of FIG. 7. On the other hand, when the clearance S is rendered zero, the thickness of the resulting layer fails to be equalized, as shown by the curve B (single-dot chain line) . Specifically, the radially outer portion of the resulting layer is unduly greater in thickness than the radially inner portion of the layer. Further, when the clearance S is in a range of 2.5-5 mm, the nonuniformity of the thickness is somewhat alleviated, as shown by the curve C (double-dot chain line) When no cover is provided at all on the fringe of the upper surface 3a, the radially outer portion of the resulting layer is unduly smaller in thickness than the radially inner portion of the layer, as shown by the curve A (broken line).

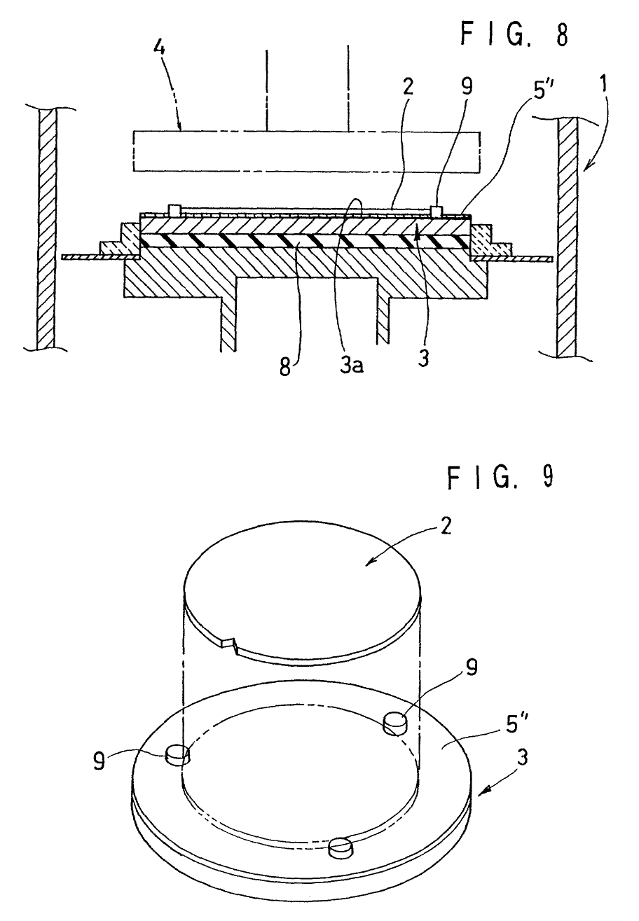

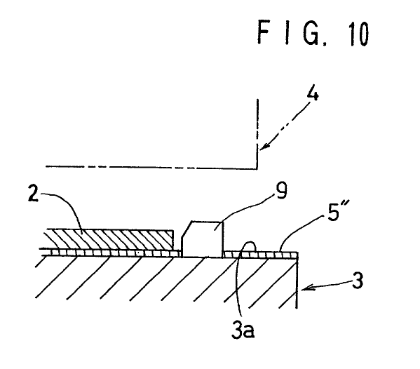

FIGS. 8-10 show a plasma treatment apparatus according to a third embodiment of the present invention. The illustrated apparatus includes a chamber 1, a lower electrode 3 on which a semiconductor substrate 2 is mounted, an upper electrode 4, an insulating layer 5″ to entirely cover the upper surface 3a of the lower electrode 3, and a supporting pad 8. The lower electrode 3 is mounted on the pad 8 which in turn is supported by the chamber 1 via an insulating member (not shown). Though not illustrated, the pad 8 is internally provided with means for heating and cooling the substrate 2 to be treated.

The upper surface 3a of the electrode 3 is flat except for the projections 9 extending upward from the surface 3a for positioning the substrate 2. The projections 9 may be formed integral with or separate from the lower electrode 3. In the illustrated example, as shown in FIG. 9, three projections are provided to be equally spaced (i.e. 120° apart) from each other around the circular substrate 2. Preferably, each of the projections 9 is made of an insulating, heat-resistant material such as ceramic, so that the projections 9, together with the insulating layer 5″, serve to equalize the plasma density between the lower and the upper electrodes 3, 4. The insulating layer 5″ may be made of a heat-resistant material such as alumina. Alternatively, the layer 5″ may be a metal oxide film formed by anodic treatment.

Clearly, the present invention is applicable not only to the above-described type of a plasma treatment apparatus provided with lower and upper electrodes, but also to the type of a plasma treatment apparatus provided with a microwave discharger cooperating with a substrate-supporting, lower electrode.

The present invention being thus described, it is obvious that the same may be varied in many ways. Such variations are not to be regarded as a departure from the spirit and scope of the present invention, and all such modifications as would be obvious to those skilled in the art are intended to be included within the scope of the following claims.

1. An electrode used for plasma treatment comprising:
a conductor provided with an upper surface which includes a first portion upon which a semiconductor substrate to be treated is mounted and a second portion around said first portion; and
an insulating member provided on the upper surface of the conductor for covering at least a part of said second portion.

2. The electrode according to claim 1, wherein the insulating member extends upward beyond said first portion.

3. The electrode according to claim 1, wherein said first portion is retreated downward from said second portion.

4. The electrode according to claim 1, further comprising a plurality of upward projections arranged around said first portion.

5. The electrode according to claim 4, wherein the upward projections are made of an insulating material.

6. The electrode according to claim 1, wherein the insulating member is spaced from the semiconductor substrate placed on said first portion.

7. The electrode according to claim 1, wherein the insulating member comprises a plate made of an insulating material.

8. The electrode according to claim 1, wherein the insulating member comprises a metal oxide layer.

9. A plasma treatment apparatus comprising:
a chamber;
a lower electrode arranged within the chamber and provided with an upper surface which includes a first portion upon which a semiconductor substrate to be treated is mounted and a second portion around said first portion;
an upper member arranged within the chamber in facing relation to the lower electrode; and
an insulating member provided on the upper surface of the lower electrode for covering at least a part of said second portion.

10. The apparatus according to claim 9, wherein said upper member comprises an electrode.

11. The apparatus according to claim 9, wherein said upper member comprises a microwave discharger.

12. A method of plasma treatment using an apparatus provided with a chamber, a lower electrode and an upper member facing the lower electrode, the method comprising the steps of:
providing insulating means around a semiconductor substrate placed on the lower electrode; and
causing a plasma discharge between the upper member and the lower electrode.
